(19) United States
(12) Patent Application Publication
(10) Pub. No.: US 2026/0154474 A1
(43) Pub. Date: Jun. 4, 2026

(54) ANOMALY DETECTION METHOD, ANOMALY DETECTION DEVICE, AND NON-TRANSITORY COMPUTER-READABLE RECORDING MEDIUM

(71) Applicant: Panasonic Intellectual Property Management Co., Ltd., Osaka (JP)

(72) Inventors: Hiroyuki OKADA, Osaka (JP); Tatsumi OBA, Chiba (JP)

(73) Assignee: Panasonic Intellectual Property Management Co., Ltd., Osaka (JP)

(21) Appl. No.: 19/460,824

(22) Filed: Jan. 27, 2026

Related U.S. Application Data
(63) Continuation of application No. PCT/JP2024/020960, filed on Jun. 10, 2024.

(30) Foreign Application Priority Data
Aug. 8, 2023 (JP) 2023-129635

(51) Int. Cl. G06F 30/20; G06T 11/65

(52) U.S. Cl. CPC G06F 30/20; G06T 11/65

(57) ABSTRACT

An anomaly detection method includes: obtaining location information indicating a location of a mobile object and operation information indicating an operation of the mobile object and associated with the location information; when the location indicated by the location information is a specific location, obtaining a driving model generated based on travel data related to past travel of at least one mobile object, among one or more mobile objects including the mobile object, and associated with the specific location; when the location indicated by the location information is the specific location, calculating an anomaly degree indicating a degree of an anomaly related to travel of the mobile object, based on the operation information and the driving model; determining whether an anomaly related to the travel of the mobile object is present, based on the anomaly degree; and outputting a result of the determining to outside.

### CROSS REFERENCE TO RELATED APPLICATIONS

This is a continuation application of PCT International Application No. PCT/JP2024/020960 filed on Jun. 10, 2024, designating the United States of America, which is based on and claims priority of Japanese Patent Application No. 2023-129635 filed on Aug. 8, 2023. The entire disclosures of the above-identified applications, including the specifications, drawings and claims are incorporated herein by reference in their entirety.

### FIELD

The present disclosure relates to an anomaly detection method, an anomaly detection device, and a non-transitory computer-readable recording medium.

### BACKGROUND

Anomaly detection methods of detecting anomalies in mobile objects have been proposed (see, for example, Patent Literature (PTL) 1).

### CITATION LIST

### Patent Literature

PTL 1: WO2021/149340

### SUMMARY

### Technical Problem

Recent years have witnessed an increasing threat of cyberattacks on mobile objects such as self-driving vehicles, executed by malicious attackers.

In view of the above, the present disclosure provides an anomaly detection method and so forth capable of detecting an anomaly related to travel of a mobile object, even when location information of such mobile object has been tampered with by a malicious attacker.

### Solution to Problem

An anomaly detection method according to an aspect of the present disclosure includes: obtaining first location information indicating a location of a mobile object and first operation information indicating an operation of the mobile object and associated with the first location information; when the location indicated by the first location information is a first specific location, obtaining a first driving model that is generated based on first travel data related to past travel of at least one mobile object and associated with the first specific location, the at least one mobile object being included in one or more mobile objects including the mobile object; when the location indicated by the first location information is the first specific location, calculating a first anomaly degree indicating a degree of an anomaly related to travel of the mobile object, based on the first operation information and the first driving model; determining whether an anomaly related to the travel of the mobile object is present, based on the first anomaly degree; and outputting a result of the determining to outside.

An anomaly detection device according to an aspect of the present disclosure includes: an information obtainer that obtains first location information indicating a location of a mobile object and first operation information indicating an operation of the mobile object and associated with the first location information; model obtainer that obtains a first driving model that is generated based on first travel data related to past travel of at least one mobile object and associated with a first specific location, when the location indicated by the first location information is the first specific location, the at least one mobile object being included in one or more mobile objects including the mobile object; an anomaly degree calculator that calculates a first anomaly degree indicating a degree of an anomaly related to travel of the mobile object, based on the first operation information and the first driving model, when the location indicated by the first location information is the first specific location; a determiner that determines whether an anomaly related to the travel of the mobile object is present, based on the first anomaly degree; and an outputter that outputs a determination result to outside.

A non-transitory computer-readable recording medium according to an aspect of the present disclosure is a non-transitory computer-readable recording medium having recorded thereon a program for causing a computer to execute anomaly detection processing, wherein the anomaly detection processing includes: obtaining first location information indicating a location of a mobile object and first operation information indicating an operation of the mobile object and associated with the first location information; when the location indicated by the first location information is a first specific location, obtaining a first driving model that is generated based on first travel data related to past travel of at least one mobile object and associated with the first specific location, the at least one mobile object being included in one or more mobile objects including the mobile object; when the location indicated by the first location information is the first specific location, calculating a first anomaly degree indicating a degree of an anomaly related to travel of the mobile object, based on the first operation information and the first driving model; determining whether an anomaly related to the travel of the mobile object is present, based on the first anomaly degree; and outputting a result of the determining to outside.

### Advantageous Effects

With an anomaly detection method and so forth according to an aspect of the present disclosure, it is possible to detect an anomaly related to travel of a mobile object, even when location information of such mobile object has been tampered with by a malicious attacker.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a block diagram showing the configuration of an anomaly detection system according to the embodiment.

FIG. 2 is a block diagram showing the configuration of a model generator according to the embodiment.

FIG. 3 is a schematic diagram showing an example of the data structure of vehicle information stored by an information obtainer according to the embodiment.

FIG. 4 is a schematic diagram showing an example of the data structure of vehicle information stored by a model obtainer according to the embodiment.

FIG. 5 is a schematic diagram showing an example of the data structure of vehicle information stored by a determiner according to the embodiment.

FIG. 6 is a flowchart of model training processing according to the embodiment.

FIG. 7 is a flowchart of classification processing according to the embodiment.

FIG. 8 is a schematic diagram showing how a classifier according to the embodiment identifies whether the driving point of a mobile object is an intersection.

FIG. 9 is a schematic diagram showing how the classifier according to the embodiment identifies the driving pattern of a mobile object.

FIG. 10 is a schematic diagram showing how the classifier according to the embodiment identifies the driving pattern of a mobile object.

FIG. 11A is a flowchart of first weighting coefficient calculation processing according to the embodiment.

FIG. 11B is a flowchart of second weighting coefficient calculation processing according to the embodiment.

FIG. 12 is a schematic diagram showing an example of how a model storage according to the embodiment stores driving models and weighting coefficients in an associated manner.

FIG. 13 is a flowchart of anomaly detection processing according to the embodiment.

FIG. 14 is a schematic diagram showing an example of how an anomaly degree calculator according to the embodiment calculates an anomaly degree related to travel of a mobile object.

FIG. 15 is a schematic diagram showing an example of the image displayed onto a display device by an outputter according to the embodiment.

FIG. 16 is a schematic diagram showing an example of the method of verifying the validity of location information about a point at which a driving route curves, as conceived by the inventors.

### DESCRIPTION OF EMBODIMENT

### Circumstances Leading to an Aspect of the Present Disclosure

In recent years, various efforts have been underway towards putting self-driving vehicles to practical use.

For example, field tests have been conducted on various services utilizing self-driving vehicles for goods delivery indoor and outdoor and for personal mobility and various services utilizing self-driving robots for cleaning and for security.

To provide secure services utilizing a self-driving vehicle, it is necessary to perform communication between the points of the self-driving vehicle and remote monitoring to enable, for example, the monitoring of the status of the self-driving vehicle and the remote operation of the self-driving vehicle in the event of an emergency.

However, the introduction of a communication system for performing communication between the points of the self-driving vehicle and the remote monitoring subjects the self-driving vehicle to the risk of becoming a target of a cyberattack executed via such communication system.

To reduce such a risk, anomaly detection devices have been proposed that are designed to cope with cyberattacks on vehicles.

Under such circumstances, there is a challenge to be addressed in introducing such an anomaly detection device, regarding a large number of false positives/false negatives in anomaly detection attributable to a wide variety of driving patterns of vehicles.

In view of this, to detect anomalies in vehicles caused by cyberattacks while reducing false positives/false negatives in anomaly detection, for example, PTL 1 proposes a method of detecting an anomaly in a vehicle, utilizing the attribute of the location indicated by location information indicating the current location of the vehicle.

However, as in the technique disclosed in PTL 1, an anomaly detection model suitable for the attribute of the current location of the vehicle (e.g., attribute such as whether the location is on a normal road or an expressway) is selected and used on the basis of the location information indicating the current location of the vehicle, on the precondition that the current location of the vehicle indicated by the location information is correct.

When the location information has been tampered with by a malicious attacker, for example, there is a possibility that anomaly detection that uses the anomaly detection model corresponding to the location indicated by such location information can be evaded. For example, when a vehicle that is incorrectly controlled is in an anomalous state of driving on a normal road at the speed of 100 km, there is a possibility that such anomaly of the vehicle fails to be detected as a result of the vehicle being determined to be driving on an expressway on the basis of the location information that has been tampered with.

It is thus necessary to verify the validity of the location information. A possible method of verifying the validity of the location information is a method in which information about the vehicle of a different type from the type of the information indicating the location of the vehicle (e.g., logs of vehicle control signals, velocity information, etc.) is converted into information indicating a location, and then the converted information indicating the location is compared with the location information.

In the process of such conversion, however, unintended locational displacement and difference can occur. For example, when a change in the location indicated by location information is estimated from information about the velocity and the angular velocity, there is a possibility that the trajectory of the driving in the locations indicated by the original items of location information is significantly different from the trajectory of the driving in the actual locations, due to friction or other effects.

For this reason, it is necessary to detect anomalies with high accuracy while avoiding false positives/false negatives in anomaly detection that can be caused by unintended locational displacement and difference.

Services utilizing self-driving vehicles are expected to expand in the future as countermeasures against labor shortages.

However, Internet of Things (IoT)-enabled self-driving vehicles are vulnerable to penetration from outside. Once penetrated, the self-driving vehicles are subjected to replay attacks by means of simple commands. It can be thus said that IoT-enabled self-driving vehicles are highly vulnerable to cyberattacks.

To cope with this, many anomaly detection methods of remotely monitoring anomalies in vehicles have been proposed. However, against the backdrop that a large number of vehicles are subjected to monitoring, the reduction of false positives/false negatives in anomaly detection is one of the challenges to be addressed.

In view of this, efforts are underway to reduce false positives/false negatives in anomaly detection by changing anomaly detection models in accordance with the current location of a mobile object, such as a self-driving vehicle, indicated by location information, to perform anomaly detection better suited to the attribute of such location. However, as described above, such efforts involve the risk that anomaly detection can be evaded when the location information has been tampered with by a malicious attacker.

In view of the above, the inventors have considered it necessary to determine whether location information itself has not been tampered with.

To detect whether the location information has been tampered with, it is necessary to verify the validity of the location information by comparing the location information with another type of information about the mobile object.

However, through the field tests and others, the inventors have arrived at the findings to be described below. That is to say, in verifying the validity of the location information by comparing the location information with another type of information about the mobile object, the points regarding which these items of information are compared cannot be just any points. More specifically, there are types of points that are suitable and not suitable for making the above comparison; points at which the mobile object operates in a driving pattern suitable for the above comparison and at which the mobile object operates in a driving pattern not suitable for the above comparison.

At points with relatively large pedestrian traffic, for example, a mobile object tends to operate more frequently in an irregular driving pattern, such as zigzagging and repeatedly traveling forward and backward, to avoid pedestrians. From this, the inventors have arrived at the finding that misrecognition can occur in verifying the validity of the location information at such points. The term “driving patterns” here refers to, for example, the classification of operations of the mobile object at a certain point, such as straight-ahead driving, right turn, left turn, U-turn, etc.

From the opposite point of view, the inventors have arrived at the finding that, at points at which a mobile object tends to operate in a specific driving pattern, such as a point at which the driving route curves, misrecognition in verifying the validity of location information validity decreases.

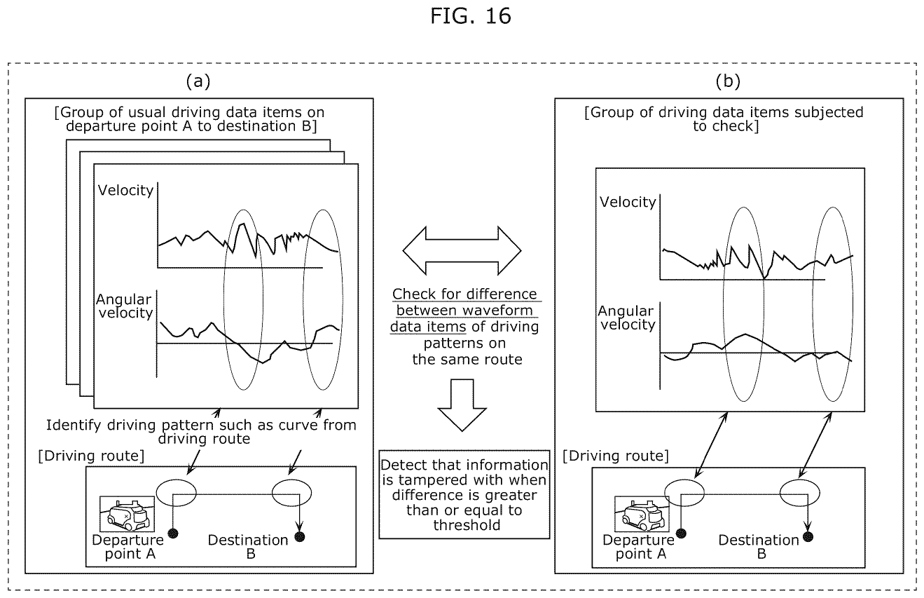

FIG. 16 is a schematic diagram showing an example of the method of verifying the validity of location information about a point at which the driving route curves, as conceived by the inventors.

(a) in FIG. 16 shows a change in the velocity and the angular velocity (time-series data) of a mobile object that traveled from departure point A to destination B in the past. (b) in FIG. 16 shows a change in the velocity and the angular velocity (time-series data) of the mobile object that newly travels from departure point A to destination B.

The inventors have found that the occurrence of misrecognition in verifying the validity of the location information decreases if the validity of the location information is verified on the basis of the a change in the velocity and the angular velocity of the mobile object in the past at points at which the mobile object tends to operate in a specific pattern (here, points corresponding to two curves curving 90 degrees to the right), and the change in the velocity and the angular velocity of the mobile object when the mobile object newly travels through such points, as shown in FIG. 16.

On the basis of the above findings, the inventors have extensively conducted further experiments and studies.

As a result, the inventors have arrived at the anomaly detection method, the anomaly detection device, and the non-transitory computer-readable recording medium according to the present disclosure to be described below.

The anomaly detection method according to an aspect of the present disclosure includes: obtaining first location information indicating a location of a mobile object and first operation information indicating an operation of the mobile object and associated with the first location information; when the location indicated by the first location information is a first specific location, obtaining a first driving model that is generated based on first travel data related to past travel of at least one mobile object and associated with the first specific location, the at least one mobile object being included in one or more mobile objects including the mobile object; when the location indicated by the first location information is the first specific location, calculating a first anomaly degree indicating a degree of an anomaly related to travel of the mobile object, based on the first operation information and the first driving model; determining whether an anomaly related to the travel of the mobile object is present, based on the first anomaly degree; and outputting a result of the determining to outside.

According to the foregoing anomaly detection method, it is possible to calculate the first anomaly degree of the mobile object at the first specific location on the basis of the first operation information indicating an operation of the mobile object and associated with the first location information indicating the first specific location at which the mobile object operates in a driving pattern that is suitable in terms of verifying the validity of the location information and the first driving model that is associated with the first specific location, and to determine whether an anomaly related to the travel of the mobile object is present on the basis of the calculated first anomaly degree. For this reason, according to the foregoing anomaly detection method, it is possible to determine that an anomaly related to the travel of the mobile object is present, when the obtained first location information has been tampered with.

As described above, according to the foregoing anomaly detection method, it is possible to detect an anomaly related to the travel of the mobile object even when the location information of such mobile object has been tampered with by a malicious attacker.

The obtaining of the first location information and the first operation information may further include obtaining: second location information indicating a location of the mobile object; and second operation information indicating an operation of the mobile object and associated with the second location information, when the location indicated by the second location information is a second specific location, the obtaining of the first driving model may further include obtaining a second driving model that is generated based on second travel data related to the past travel of the at least one mobile object and associated with the second specific location; when the location indicated by the second location information is the second specific location, the calculating of the first anomaly degree may further include calculating a second anomaly degree indicating a degree of an anomaly related to the travel of the mobile object, based on the second operation information and the second driving model, and the determining may be performed based on the first anomaly degree and the second anomaly degree.

According to the foregoing anomaly detection method, it is possible to determine whether an anomaly related to the travel of the mobile object is present on the basis of the first anomaly degree at the first specific location at which the mobile object operates in a driving pattern that is suitable in terms of verifying the validity of the location information and the second anomaly degree at the second specific location at which the mobile object operates in a driving pattern that is suitable in terms of verifying the validity of the location information.

With this, according to the foregoing anomaly detection method, it is possible to detect an anomaly related to the travel of the mobile object with a higher accuracy.

The foregoing anomaly detection method may further include calculating a first weighted anomaly degree based on the first anomaly degree and a first weighting coefficient that is associated with the location indicated by the first location information, and calculating a second weighted anomaly degree based on the second anomaly degree and a second weighting coefficient that is associated with the location indicated by the second location information, wherein the determining may be performed based on the first weighted anomaly degree and the second weighted anomaly degree.

According to the foregoing anomaly detection method, it is possible to determine whether an anomaly related to the travel of the mobile object is present on the basis of the first weighted anomaly degree obtained by assigning, to the first anomaly degree, a weight associated with the first location and the second weighted anomaly degree obtained by assigning, to the second anomaly degree, a weight associated with the second location.

With this, according to the foregoing anomaly detection method, it is possible to detect an anomaly related to the travel of the mobile object with a higher accuracy.

The foregoing anomaly detection method may further include: calculating a third weighted anomaly degree based on the first anomaly degree and a third weighting coefficient that is associated with the first driving model, and calculating a fourth weighted anomaly degree based on the second anomaly degree and a fourth weighting coefficient that is associated with the second driving model, wherein the determining may be performed based on the third weighted anomaly degree and the fourth weighted anomaly degree.

According to the foregoing anomaly detection method, it is possible to determine whether an anomaly related to the travel of the mobile object is present on the basis of the third weighted anomaly degree obtained by assigning, to the first anomaly degree, a weight associated with the first driving model and the fourth weighted anomaly degree obtained by assigning, to the second anomaly degree, a weight associated with the second driving model.

With this, according to the foregoing anomaly detection method, it is possible to detect an anomaly related to the travel of the mobile object with a higher accuracy.

Further, the obtaining of the first location information and the first operation information may further include obtaining: first time information indicating a first time and associated with the first location information; and second time information indicating a second time and associated with the second location information. The foregoing anomaly detection method may further include: calculating a fifth weighted anomaly degree based on the first anomaly degree and a fifth weighting coefficient that is based on the first time indicated by the first time information, and calculating a sixth weighted anomaly degree based on the second anomaly degree and a sixth weighting coefficient that is based on the second time indicated by the second time information, and the determining may be performed based on the fifth weighted anomaly degree and the sixth weighted anomaly degree.

According to the foregoing anomaly detection method, it is possible to determine whether an anomaly related to the travel of the mobile object is present on the basis of the fifth weighted anomaly degree obtained by assigning, to the first anomaly degree, a weight using the decay coefficient corresponding to the first time at which the first location information is obtained and the sixth weighted anomaly degree obtained by assigning, to the second anomaly degree, a weight using the decay coefficient corresponding to the second time at which the second location information is obtained.

With this, according to the foregoing anomaly detection method, it is possible to detect an anomaly related to the travel of the mobile object with a higher accuracy.

Further, the obtaining of the first driving model may include obtaining a third driving model that is the first driving model associated with a manufacturer of the mobile object, the calculating of the first anomaly degree may include calculating a third anomaly degree that is the first anomaly degree that is based on the first operation information and the third driving model, and the determining may be performed based on the third anomaly degree.

According to the foregoing anomaly detection method, it is possible to determine whether an anomaly related to the travel of the mobile object is present, using the third driving model corresponding to the manufacturer of the mobile object.

With this, according to the foregoing anomaly detection method, it is possible to detect an anomaly related to the travel of the mobile object with a higher accuracy.

Further, the first operation information may include at least one of velocity information indicating a velocity of the mobile object or angular velocity information indicating an angular velocity of the mobile object.

With this, according to the foregoing anomaly detection method, it is possible to detect an anomaly related to the travel of the mobile object on the basis of the velocity of the mobile object or/and the angular velocity of the mobile object.

Further, the outputting may be performed by generating an output image and displaying the output image onto a display, the output image being an image showing the result of the determining that is superimposed on a map including the location indicated by the first location information.

With this, according to the foregoing anomaly detection method, it is possible for a user using the foregoing anomaly detection method, to visually recognize the situation when an anomaly related to the travel of the mobile object has occurred.

The foregoing anomaly detection method may further include generating the first driving model based on the first travel data.

With this, according to the foregoing anomaly detection method, it is possible to generate the first driving model.

Further, the generating may include: generating one or more driving models including the first driving model, based on a plurality of items of travel data including the first travel data; and individually classifying the plurality of items of travel data into one of a plurality of classification categories that include one or more classification categories and correspond one-to-one to the one or more driving models, and generating the one or more driving models based on one or more of the plurality of items of travel data classified into the one or more classification categories.

With this, according to the foregoing anomaly detection method, it is possible to generate one or more driving models corresponding one-to-one to the one or more classification categories.

The foregoing anomaly detection method may further include calculating, for each of the one or more driving models, a weighting coefficient indicating a reliability of the driving model and associated with the driving model.

With this, according to the foregoing anomaly detection method, it is possible to calculate, for each of a plurality of first driving models to be generated, the weighting coefficient indicating the reliability.

The anomaly detection device according to an aspect of the present disclosure includes: an information obtainer that obtains first location information indicating a location of a mobile object and first operation information indicating an operation of the mobile object and associated with the first location information; a model obtainer that obtains a first driving model that is generated based on first travel data related to past travel of at least one mobile object and associated with a first specific location, when the location indicated by the first location information is the first specific location, the at least one mobile object being included in one or more mobile objects including the mobile object; an anomaly degree calculator that calculates a first anomaly degree indicating a degree of an anomaly related to travel of the mobile object, based on the first operation information and the first driving model, when the location indicated by the first location information is the first specific location; a determiner that determines whether an anomaly related to the travel of the mobile object is present, based on the first anomaly degree; and an outputter that outputs a determination result to outside.

According to the foregoing anomaly detection device, it is possible to calculate the first anomaly degree of the mobile object at the first specific location on the basis of the first operation information indicating an operation of the mobile object and associated with the first location information indicating the first specific location at which the mobile object operates in a driving pattern that is suitable in terms of verifying the validity of the location information and the first driving model that is associated with the first specific location, and to determine whether an anomaly related to the travel of the mobile object is present on the basis of the calculated first anomaly degree. For this reason, according to the foregoing anomaly detection device, it is possible to determine that an anomaly related to the travel of the mobile object is present, when the obtained first location information has been tampered with.

As described above, according to the foregoing anomaly detection device, it is possible to detect an anomaly related to the travel of the mobile object even when the location information of such mobile object has been tampered with by a malicious attacker.

The non-transitory computer-readable recording medium according to an aspect of the present disclosure is a non-transitory computer-readable recording medium having recorded thereon a program for causing a computer to execute anomaly detection processing, wherein the anomaly detection processing includes: obtaining first location information indicating a location of a mobile object and first operation information indicating an operation of the mobile object and associated with the first location information; when the location indicated by the first location information is a first specific location, obtaining a first driving model that is generated based on first travel data related to past travel of at least one mobile object and associated with the first specific location, the at least one mobile object being included in one or more mobile objects including the mobile object; when the location indicated by the first location information is the first specific location, calculating a first anomaly degree indicating a degree of an anomaly related to travel of the mobile object, based on the first operation information and the first driving model; determining whether an anomaly related to the travel of the mobile object is present, based on the first anomaly degree; and outputting a result of the determining to outside.

According to the foregoing non-transitory computer-readable recording medium, it is possible to calculate the first anomaly degree of the mobile object at the first specific location on the basis of the first operation information indicating an operation of the mobile object and associated with the first location information indicating the first specific location at which the mobile object operates in a driving pattern that is suitable in terms of verifying the validity of the location information and the first driving model that is associated with the first specific location, and to determine whether an anomaly related to the travel of the mobile object is present on the basis of the calculated first anomaly degree. For this reason, according to the foregoing non-transitory computer-readable recording medium, it is possible to determine that an anomaly related to the travel of the mobile object is present, when the obtained first location information has been tampered with.

As described above, according to the foregoing non-transitory computer-readable recording medium, it is possible to detect an anomaly related to the travel of the mobile object even when the location information of such mobile object has been tampered with by a malicious attacker.

Hereinafter, a certain exemplary embodiment of the anomaly detection system according to an aspect of the present disclosure is described in greater detail with reference to the accompanying Drawings. The exemplary embodiment described below shows a specific example of the present disclosure. The numerical values, shapes, elements, the arrangement and connection of the elements, steps (processes), the processing order of the steps etc. shown in the following exemplary embodiment are mere examples, and therefore do not limit the scope of the present disclosure. The drawings are schematic diagrams, and thus they are not always exactly illustrated. Also, substantially the same elements are assigned the same reference marks throughout the drawings, and overlapping description may be omitted or simplified.

### Embodiment

The following describes an anomaly detection system according to an embodiment.

This anomaly detection system is a system that detects an anomaly related to travel of a mobile object that is subjected to anomaly detection.

### Configuration

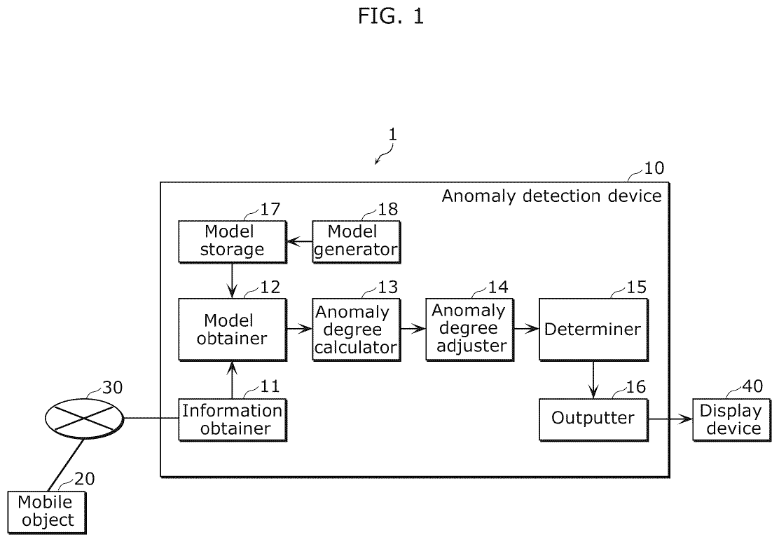

FIG. 1 is a block diagram showing the configuration of anomaly detection system 1 according to the embodiment.

As shown in FIG. 1, anomaly detection system 1 includes anomaly detection device 10, mobile object 20, network 30, and display device 40.

Network 30, which is connected to a plurality of devices including mobile object 20 and anomaly detection device 10, enables communication between the devices to which network 30 is connected. Network 30 is, for example, the Internet.

Display device 40 is connected to anomaly detection device 10 and displays an image outputted from anomaly detection device 10. Display device 40 is, for example, a display.

The description here assumes that display device 40 is an external device of the anomaly detection device. However, as another example of the configuration, display device 40 may also be, for example, a constituent element of anomaly detection device 10.

Mobile object 20 is a mobile object that is subjected to anomaly detection in anomaly detection system 1.

FIG. 1 illustrates only a single mobile object 20, but anomaly detection system 1 is not necessarily limited to including only one mobile object 20 that is subjected to anomaly detection; anomaly detection system 1 may also include two or more mobile objects. To avoid complication, the description here assumes that one mobile object 20 is present.

Mobile object 20 is a self-driving device. Examples of mobile object 20 include a self-driving vehicle for goods delivering, a self-driving vehicle for personal mobility, a self-driving robot for cleaning, a self-driving robot for security, etc.

Mobile object 20 sequentially transmits, to anomaly detection device 10 via network 30, vehicle control signals, each including location information indicating a location of mobile object 20 and operation information indicating an operation of mobile object 20 and associated with the location information.

The operation information is, for example, velocity information indicating the velocity of mobile object 20 or/and angular velocity information indicating the angular velocity of mobile object 20.

Mobile object 20, for example, may sequentially transmit, to anomaly detection device 10, vehicle control signals that are sequentially exchanged in a mobile object network constructed within mobile object 20 when mobile object 20 operates in self-driving.

Mobile object 20 may transmit vehicle control signals to anomaly detection device 10 through, for example, Virtual Private Network (VPN) communication. This enables mobile object 20 to transmit vehicle control signals to anomaly detection device 10 in a relatively secured manner.

Anomaly detection device 10 detects an anomaly related to the travel of mobile object 20 on the basis of the vehicle control signals transmitted from mobile object 20.

Anomaly detection device 10 may be realized, for example, in a computer device that includes a processor (e.g., Central Processing Unit (CPU)) and a memory (e.g., Read-Only Memory (ROM)) or/and Random Access Memory (RAM)) by means of the processor executing a program stored in the memory. In this case, anomaly detection device 10 may be realized, for example, in one or more computer devices capable of communicating with each other in a cloud or on-premises environment.

As shown in FIG. 1, anomaly detection device 10 includes information obtainer 11, model obtainer 12, anomaly degree calculator 13, anomaly degree adjuster 14, determiner 15, outputter 16, model storage 17, and model generator 18.

Information obtainer 11 sequentially receives the vehicle control signals that are sequentially transmitted from mobile object 20, and sequentially obtains, from each of the received vehicle control signals, the location information and the operation information included in such vehicle control signal. More specifically, information obtainer 11 sequentially generates, from each of the vehicle control signals that are sequentially received, vehicle information including the location information and the operation information included in such vehicle control signal, and stores the generated vehicle information.

Model storage 17 stores, for each of one or more predetermined specific locations, one or more driving models that are generated on the basis of travel data related to the past travel of at least one mobile object among one or more mobile objects including mobile object 20 and associated with such specific location.

Each of the one or more driving models is, for example, a change (time-series data) in the velocity or/and the angular velocity of the at least one mobile object in a specific driving pattern at a specific point.

The description here assumes that model storage 17 stores one or more driving models generated by model generator 18 to be described later. However, as another example of the configuration, model storage 17 may store one or more driving models that are generated by an external device of anomaly detection device 10. In this case, anomaly detection device 10 does not include model generator 18.

When the location indicated by location information obtained by information obtainer 11 is one of the one or more predetermined specific locations, model obtainer 12 obtains, from model storage 17, the driving model associated with such specific location.

As described above, information obtainer 11 sequentially obtains location information and operation information. For this reason, every time the location indicated by location information obtained by information obtainer 11 is one of the one or more predetermined specific locations, model obtainer 12 obtains the driving model associated with such specific location.

Anomaly degree calculator 13 calculates the anomaly degree indicating the degree of an anomaly related to the travel of mobile object 20, when the location indicated by location information obtained by information obtainer 11 is one of the one or more predetermined specific locations, on the basis of (1) the operation information associated with such location information, obtained by information obtainer 11 and (2) the driving model associated with such specific location, obtained by model obtainer 12.

As described above, information obtainer 11 sequentially obtains location information and operation information. For this reason, anomaly degree calculator 13 calculates an anomaly degree every time the location indicated by location information obtained by information obtainer 11 is one of the one or more predetermined specific locations.

Anomaly degree adjuster 14 adjusts an anomaly degree when anomaly degree calculator 13 has calculated such anomaly degree. The description here assumes that anomaly degree adjuster 14 performs weighting for each anomaly degree, using the weighting coefficient corresponding to such anomaly degree, thereby calculating a weighted anomaly degree obtained by performing the weighting. More specifically, a weighting coefficient is a value between 0 and 1, inclusive, and anomaly degree adjuster 14 calculates the weighted anomaly degree by multiplying each anomaly degree by the weighting coefficient corresponding to such anomaly degree.

A weighting coefficient may also be, for example, a weighting coefficient associated one-to-one with the one or more specific locations, or/and a weighting coefficient associated one-to-one with the one or more driving models, or/and a weighting coefficient that is based on the time at which location information is obtained by information obtainer 11.

As described above, anomaly degree calculator 13 sequentially calculates anomaly degrees. For this reason, anomaly degree adjuster 14 calculates a weighted anomaly degree every time anomaly degree calculator 13 calculates an anomaly degree.

Determiner 15 determines whether an anomaly related to the travel of mobile object 20 is present, on the basis of a weighted anomaly degree calculated by anomaly degree adjuster 14.

As described above, anomaly degree adjuster 14 sequentially calculates weighted anomaly degrees. For this reason, determiner 15 determines whether an anomaly related to the travel of mobile object 20 is present, every time anomaly degree adjuster 14 calculates a weighted anomaly degree, on the basis of one or more weighted anomaly degrees calculated by anomaly degree adjuster 14 up until such point in time.

Outputter 16 outputs, to outside, the result of the determination performed by determiner 15. The description here assumes, as a non-limiting example, that outputter 16 generates an image showing the result of the determination and outputs the generated image onto display device 40, which is an external device. As another example, outputter 16 may also generate voice representing the result of the determination and output the generated voice to a speaker, which is an external device.

Model generator 18 generates one or more driving models to be stored by model storage 17.

The description here assumes that model generator 18 generates one or more driving models by training machine learning models corresponding one-to-one to the one or more driving models, using travel data that is related to the past travel of at least one mobile object among the one or more mobile objects including mobile object 20 and is obtained during a predetermined model training period.

Note that since the travel data related to the past travel of the at least one mobile object is updated in the course of a daily operation of the at least one mobile object, model generator 18 may generate and update one or more driving models at regular time intervals.

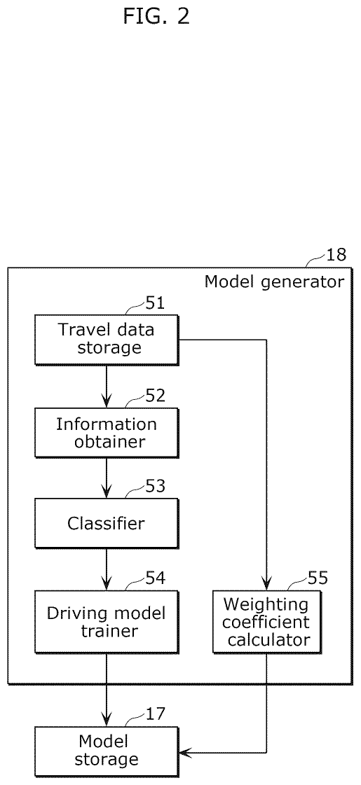

FIG. 2 is a block diagram showing the configuration of model generator 18.

As shown in FIG. 2, model generator 18 includes travel data storage 51, information obtainer 52, classifier 53, driving model trainer 54, and weighting coefficient calculator 55.

Travel data storage 51 stores the travel data related to the past travel of the at least one mobile object among the one or more mobile objects including mobile object 20.

The description here assumes that the travel data is vehicle control signals, each including location information indicating a location of the at least one mobile object and operation information indicating an operation of the at least one mobile object and associated with the location information.

Information obtainer 52 obtains, from travel data storage 51, vehicle control signals obtained during the predetermined model training period.

Classifier 53 classifies the vehicle control signals obtained by information obtainer 52 into one of a plurality of classification categories, including one or more classification categories, corresponding one-to-one to the one or more driving models, in accordance with the driving location or/and the driving pattern of the at least one mobile object, on the basis of predetermined settings information.

Driving model trainer 54 generates one or more driving models on the basis of one or more of the vehicle control signals classified into the one or more classification categories. The description here assumes that driving model trainer 54 generates the one or more driving models by training machine learning models corresponding one-to-one to the one or more driving models, using one or more of the vehicle control signals classified into the one or more classification categories.

Driving model trainer 54 then stores, in model storage 17, the generated one or more driving models.

Weighting coefficient calculator 55 calculates, for each of the one or more driving models generated by driving model trainer 54, a weighting coefficient indicating the reliability of such driving model.

Weighting coefficient calculator 55 then stores, in model storage 17, the calculated weighting coefficients and the corresponding driving models in an associated manner.

### Data Structure

The following describes the structure of data handled by anomaly detection device 10.

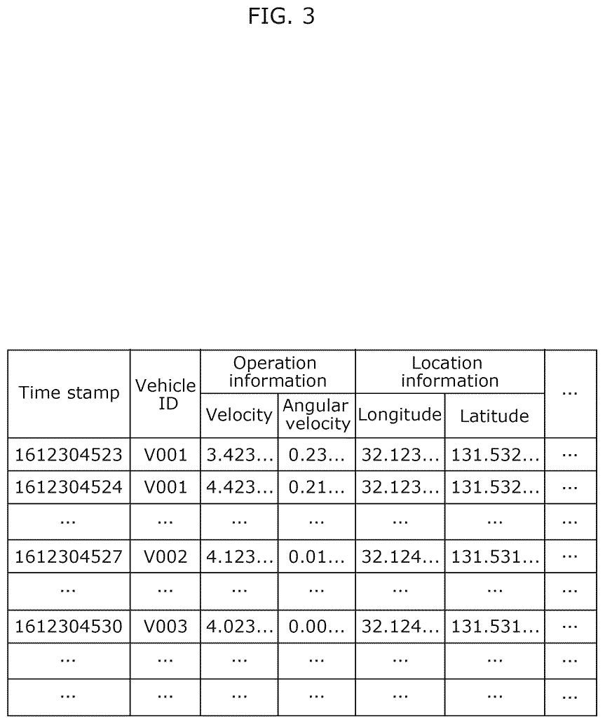

FIG. 3 is a schematic diagram showing an example of the data structure of vehicle information including: location information indicating a location of mobile object 20 generated and stored by information obtainer 11 on the basis of a vehicle control signal transmitted from mobile object 20; and operation information indicating an operation of mobile object 20 and associated with the location information.

Information obtainer 11 obtains vehicle control signals transmitted from mobile object 20 using a protocol such as Controller Area Network (CAN), FlesRay, etc., or in a data format such as Robot Operating System (ROS). Information obtainer 11 then analyzes each of the obtained vehicle control signals to generate vehicle information.

As shown in FIG. 3, each vehicle information stored by information obtainer 11 includes the following items that are associated with each other: a timestamp indicating the time at which a vehicle control signal is generated; a vehicle ID, which is an identifier of mobile object 20; operation information indicating an operation of mobile object 20; and location information indicating a location of mobile object 20.

The description here assumes that the operation information is the velocity of mobile object 20 and the angular velocity of mobile object 20.

Each vehicle information may also include, for example, information related to device operations of mobile object 20 while in operation (e.g., information indicating the usage status of turn signals, hazard lights, etc.).

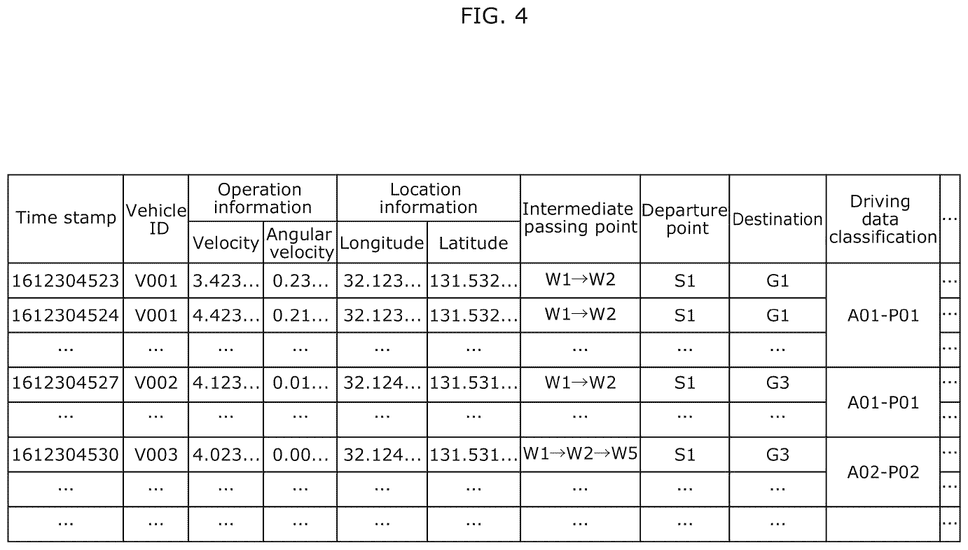

FIG. 4 shows vehicle information to be stored by model obtainer 12 after model obtainer 12 adds, to each vehicle information stored by information obtainer 11, information for obtaining a driving model from model storage 17.

As shown in FIG. 4, in addition to the timestamp, the vehicle ID, the operation information, and the location information, each vehicle information to be stored by model obtainer 12 includes the following items that are associated with each other: an intermediate passing point indicating intermediate points passed through by mobile object 20 while traveling; a departure point of the travel of mobile object 20; a destination of the travel of mobile object 20; and driving data classification indicating a classification category into which the vehicle information is classified.

Model obtainer 12 analyzes the items of location information and operation information for all the processes of one travel performed by one mobile object 20, for example, thereby generating the intermediate passing points, the departure point, and the destination.

Model obtainer 12 also analyzes the items of location information and operation information for one or more series of travels included in the one travel performed by one mobile object 20, for example, thereby classifying a series of vehicle control signals corresponding to the items of location information and operation information of such series of travels into one of the plurality of classification categories.

Here, model obtainer 12 may classify, into one of the plurality of classification categories, a first series of vehicle control signals corresponding to a first series of location information and operation information included in the one travel, and may classify, into another of the plurality of classification categories, a second series of vehicle control signals corresponding to a second series of location information and operation information included in the one travel.

The plurality of classification categories include, for example: classification category A01-P01 indicating that mobile object 20 operates in a driving pattern indicated by driving pattern P01 at area A01 among the one or more predetermined specific locations; and classification category A02-P02 indicating that mobile object 20 operates in a driving pattern indicated by driving pattern P02 at area A02 among the one or more predetermined specific locations.

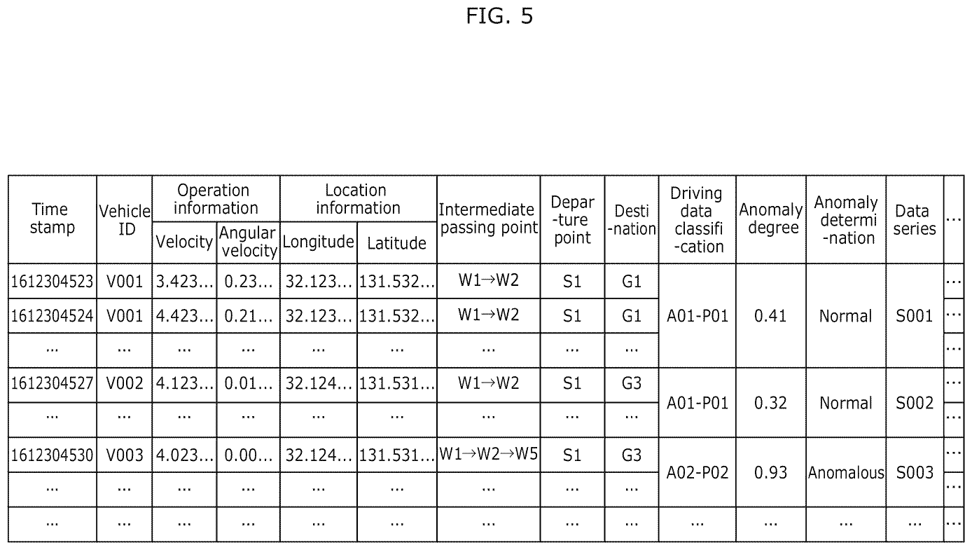

FIG. 5 shows vehicle information to be stored by determiner 15 after determiner 15 adds, to each vehicle information stored by model obtainer 12, information indicating the result of a determination of whether an anomaly related to the travel of mobile object 20 is present.

As shown in FIG. 5, in addition to the timestamp, the vehicle ID, the operation information, the location information, the intermediate passing point, the departure point, the destination, the driving data classification, each vehicle information stored by determiner 15 further includes the following items that are associated with each other: an anomaly degree calculated by anomaly degree calculator 13; an anomaly determination indicating the result of a determination performed by determiner 15 of whether an anomaly related to the travel of mobile object 20 is present; and data series for identifying a series of vehicle information subjected to the determination performed by determiner 15 of whether an anomaly related to the travel of mobile object 20 is present.

### Operation

Anomaly detection device 10 performs model training processing for generating driving models and anomaly detection processing for detecting anomalies related to the travel of mobile object 20.

The following describes the model training processing and the anomaly detection processing performed by anomaly detection device 10 with reference to the drawings.

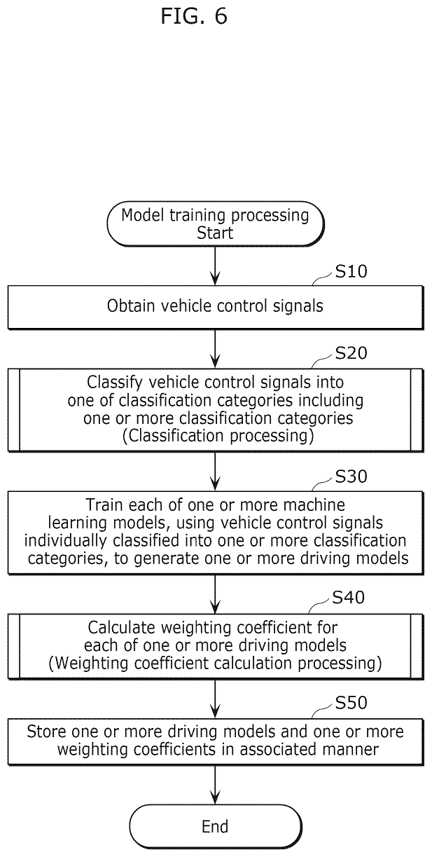

FIG. 6 is a flowchart of the model training processing performed by anomaly detection device 10.

As shown in FIG. 6, when the model training processing starts, information obtainer 52 obtains, from travel data storage 51, the travel data (here, vehicle control signals) obtained during the predetermined model training period (step S10).

After the vehicle control signals are obtained, classifier 53 classifies the vehicle control signals obtained by information obtainer 52 into one of the plurality of classification categories, including one or more classification categories, corresponding one-to-one to the one or more driving models, in accordance with the driving location or/and the driving pattern of at least one mobile object, on the basis of the predetermined settings information (step S20).

The description here assumes that classifier 53 classifies the vehicle control signals into one of the plurality of classification categories, including one or more classification categories, corresponding one-to-one to the one or more driving models, in accordance with the driving location and the driving pattern of the at least one mobile object.

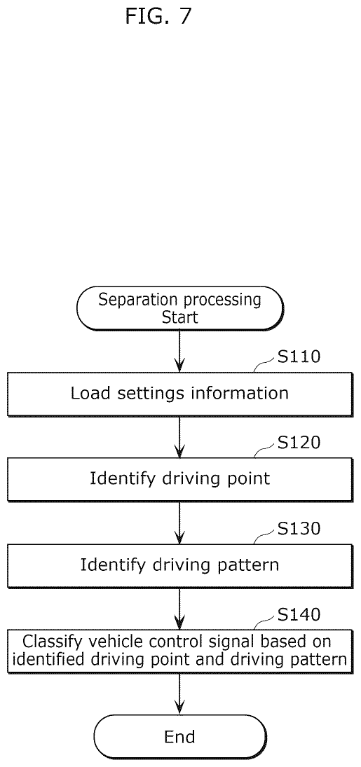

A specific example of the method of the classification performed by classifier 53 will be described later with reference to the flowchart in FIG. 7.

After the vehicle control signals are classified, driving model trainer 54 individually generates one or more driving models by training machine learning models corresponding one-to-one to the driving models, using one or more of the vehicle control signals classified into the one or more classification categories (step S30).

After the one or more driving models are generated, weighting coefficient calculator 55 calculates, for each of the one or more driving models, a weighting coefficient indicating the reliability of such driving model (step S40).

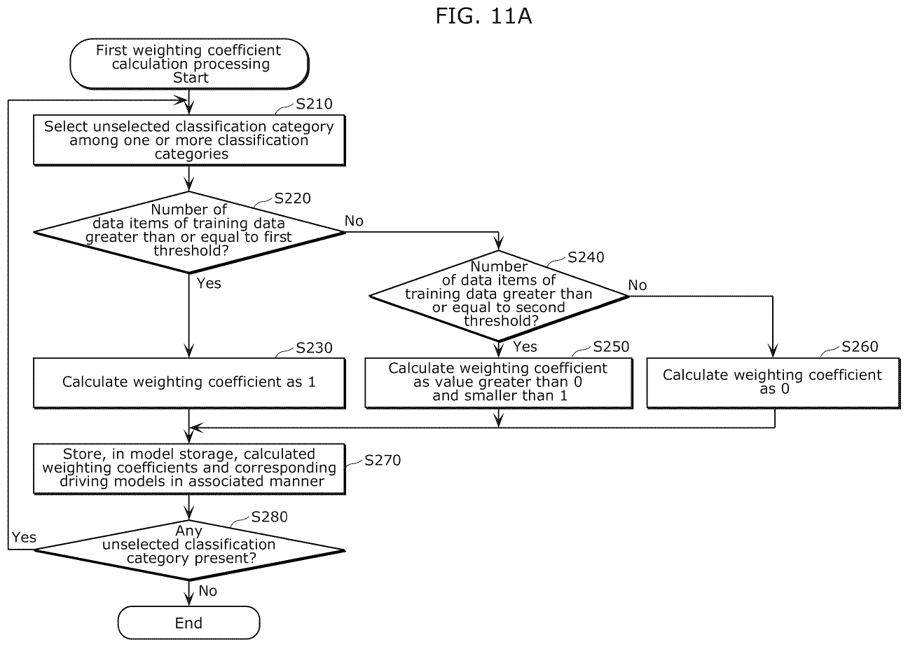

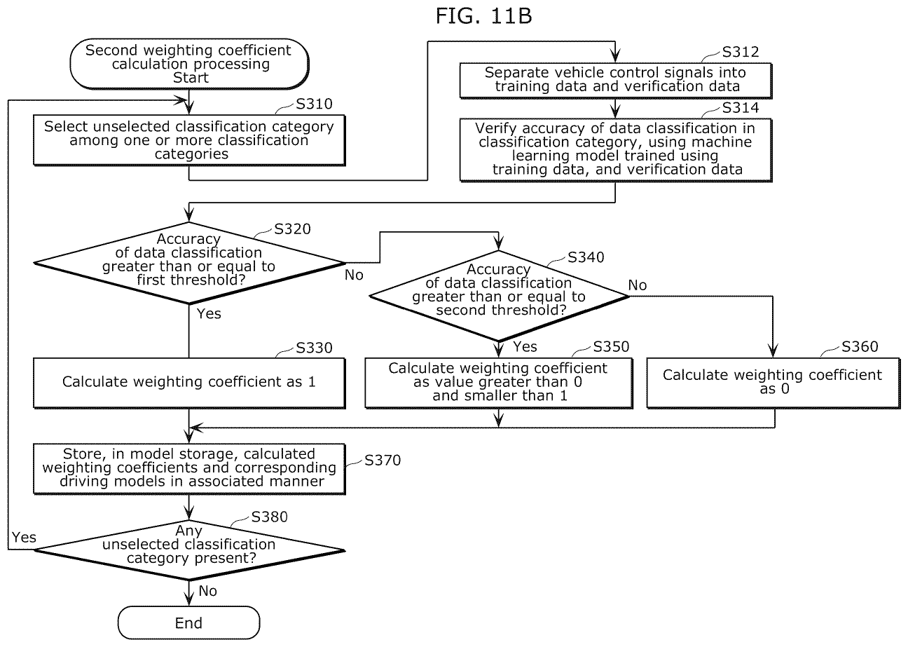

A specific example of the calculation of weighting coefficients performed by weighting coefficient calculator 55 will be described later with reference to the flowcharts in FIG. 11A and FIG. 11B.

After the weighting coefficients for the one or more driving models are calculated, model storage 17 stores the one or more driving models generated by driving model trainer 54 and the one or more weighting coefficients generated by weighting coefficient calculator 55 in an associated manner (step S50).

After the process of step S50 is completed, the model training processing ends.

FIG. 7 is a flowchart of the classification processing showing a specific example of the classification performed by classifier 53 in the process of step S20.

As shown in FIG. 7, when the classification processing starts, classifier 53 loads the predetermined settings information related to the driving model (step S110).

The settings information is information used to classify data to be used, in accordance with the attribute of a driving model to be generated.

For example, when the driving model to be generated is a driving model for detecting the difference between the following items to have a grasp of whether the location information has been tampered with: the travel route estimated from a change in the velocity and the angular velocity in driving patterns such as right turn, left turn, straight-forward driving, and U-turn at an intersection or other locations; and a change in the location indicated by the location information at such intersection or other locations, the settings information includes information indicating that the location subjected to the classification is an intersection and that the driving patterns subjected to the classification are right turn, left turn, straight-forward driving, and U-turn.

The description of the present embodiment assumes that the driving model to be generated is a driving model for detecting the difference between the following items to have a grasp of whether the location information has been tampered with: the travel route estimated from a change in the velocity and the angular velocity in driving patterns such as right turn, left turn, straight-forward driving, and U-turn at an intersection or other locations; and a change in the location indicated by the location information at such intersection or other locations.

After loading the settings information, classifier 53 identifies, from the location information included in the vehicle control signal, the driving point of the mobile object whose location is indicated by such location information, using information about a route or/and a point set in advance using, for example, map information (step S120).

Here, “identifies, from the location information included in the vehicle control signal, the driving point of the mobile object whose location is indicated by such location information” refers to the act of determining whether the driving point of mobile object 20 indicated by the location information is a route or/and a point set in advance using, for example, map information, etc. Stated differently, it refers to the act of determining whether the driving point of mobile object 20 whose location is indicated by the location information is a specific location.

“A route or/and a point set in advance using, for example, map information, etc.” is, for example, information used to determine whether the driving point of mobile object 20 whose location is indicated by the location information is an intersection, a one-way street, a pedestrian-only road, etc.

The description of the present embodiment assumes that information “related to a route or/and a point set in advance using, for example, map information, etc.” is information used to determine whether the driving point is an intersection.

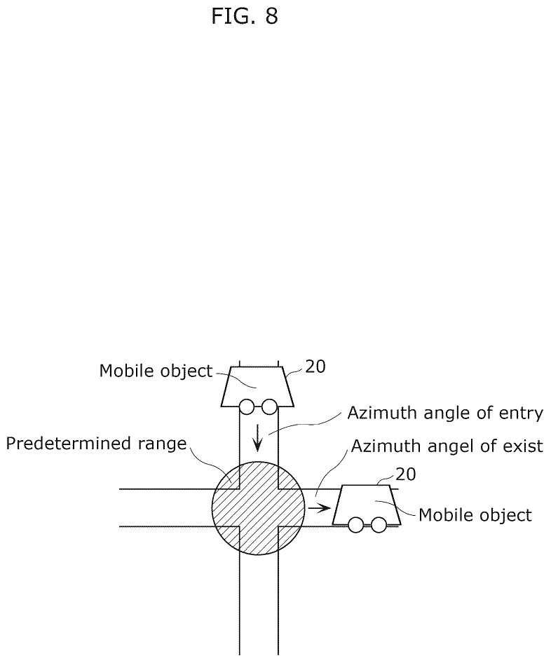

FIG. 8 is a schematic diagram showing how classifier 53 identifies whether the driving point of mobile object 20 whose location is indicated by the location information is an intersection.

A possible method of determining whether the driving point of mobile object 20 whose location is indicated by the location information is an intersection is, for example, as shown in FIG. 8, a method in which such determination is made on the basis of whether the driving point of mobile object 20 whose location is indicated by the location information is in a region within a predetermined range from the center location of the intersection.

With reference to FIG. 7 again, the description of the classification processing will be continued.

After the driving point of mobile object 20 whose location is indicated by the location information is identified, classifier 53 identifies the driving pattern of mobile object 20 at such point from a change in the location of mobile object 20 indicated by the location information at such point (step S130).

The description of the present embodiment assumes that the driving pattern to be identified is one of straight-forward driving, right turn, left turn, or U-turn.

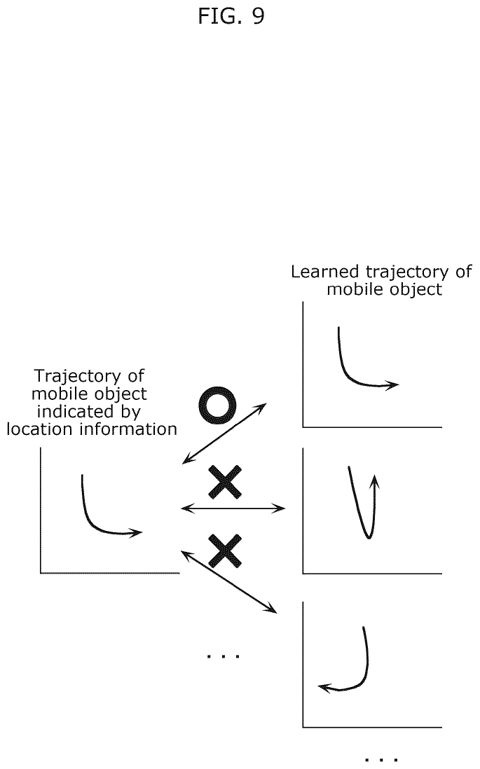

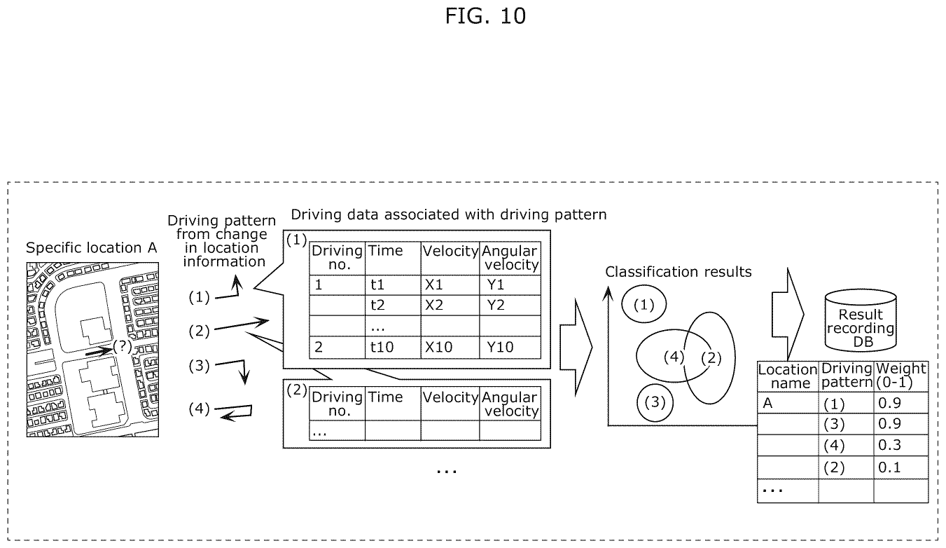

FIG. 9 and FIG. 10 are schematic diagrams showing how classifier 53 identifies the driving pattern of mobile object 20 whose location is indicated by the location information.

A possible method of identifying the driving pattern of mobile object 20 whose location is indicated by the location information from a change in the location of mobile object 20 whose location is indicated by the location information, for example, may be a method, as shown in FIG. 8, used to determine whether the driving point of mobile object 20 indicated by the location information is an intersection, in which the driving pattern of mobile object 20 is identified by calculating the difference between the azimuth angle at which mobile object 20 enters the region within the predetermined range from the center location of the intersection and the azimuth angle at which mobile object 20 exits such region, and then determining whether such calculated difference is at a threshold.

Another possible method, for example, is a method, as shown in FIG. 9, in which the driving pattern of mobile object 20 whose location is indicated by the location information is identified by learning, in advance, the trajectories of a plurality of mobile objects in the respective driving patterns, using a technique handling time-series waveform data known as Shaplets, to determine which one of the driving patterns the trajectory of mobile object 20 whose location is indicated by the location information resembles.

Further another possible method, for example, may be a method, as shown in FIG. 10, in which the driving pattern of mobile object 20 whose location is indicated by the location information is identified by clustering, in advance, a change in the velocity or/and the angular velocity of each of a plurality of mobile objects in the respective driving patterns, to determine which one of the driving patterns the velocity or/and the angular velocity of mobile object 20 whose location is indicated by the location information resembles.

With reference to FIG. 7 again, the description of the classification processing will be continued.

After the driving point and the driving pattern of mobile object 20 whose location is indicated by the location information are identified, classifier 53 classifies the vehicle control signal including such location information into one of the plurality of classification categories on the basis of the driving point and the driving pattern that have been identified (step S140).

After the process of step S140 is completed, the classification processing ends.

FIG. 11A and FIG. 11B are flowcharts of first weighting coefficient calculation processing and second weighting coefficient calculation processing, respectively, showing specific examples of the calculation of weighting coefficients performed by weighting coefficient calculator 55 in the process of step S40.

Here, the first weighting coefficient calculation processing is processing performed by weighting coefficient calculator 55 to calculate weighting coefficients in accordance with the number of data items of vehicle control signals, which are training data items for training machine learning models. The second weighting coefficient calculation processing is processing performed by weighting coefficient calculator 55 to verify the accuracy of the trained machine learning models, and to calculate weighting coefficients on the basis of the result of the verification.

In the first weighting coefficient calculation processing and the second weighting coefficient calculation processing, weighting coefficients to be calculated are values between 0 and 1, inclusive. The weighting coefficients calculated through these processing are used by anomaly degree calculator 14 to calculate weighted anomaly degrees.

FIG. 11A is a flowchart of the first weighting calculation processing performed by weighting coefficient calculator 55.

When the first weighting coefficient calculation processing starts, weighting coefficient calculator 55 selects an unselected classification category from among the one or more classification categories (step S210). Here, “unselected classification category” refers to a classification category that has not yet been selected in the loop processing formed of the process from step S210 to the process of step S280: Yes to be described later.

After an unselected classification category is selected, weighting coefficient calculator 55 determines whether the number of vehicle control signals included in the selected classification category, i.e., the number of data items of training data, is greater than or equal to a first threshold (step S220).

In the process of step S220, when the number of data items of training data is greater than or equal to the first threshold (step S220: Yes), weighting coefficient calculator 55 calculates the weighting coefficient as 1 (step S230).

In the process of step S220, when the number of data items of training data is not greater than or equal to the first threshold (step S220: No), weighting coefficient calculator 55 further determines whether the number of data items of training data is greater than or equal to a second threshold, which is smaller than the first threshold (step S240).

In the process of step S240, when the number of data items of training data is greater than or equal to the second threshold (step S240: Yes), weighting coefficient calculator 55 calculates the weighting coefficient as a value that is greater than 0 and smaller than 1. In so doing, weighting coefficient calculator 55 calculates the weighting coefficient to cause the value of the weighting coefficient to be larger as the number of data items is larger, in accordance with the number of data items of training data (Step S250).

In the process of step S240, when the number of data items of training data is not greater than or equal to the second threshold (step S240: No), weighting coefficient calculator 55 calculates the weighting coefficient as 0 (step S260).

When the process of step S230 ends, when the process of step S250 ends, and when the process of step S260 ends, weighting coefficient calculator 55 stores, in model storage 17, the calculated weighting coefficients and the corresponding driving models in an associated manner (step S270).

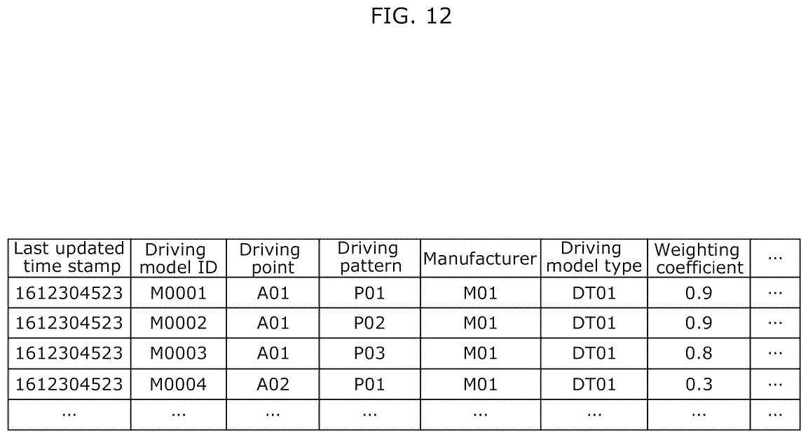

FIG. 12 is a schematic diagram showing an example of how model storage 17 stores driving models and weighting coefficients in an associated manner.

As shown in FIG. 12, model storage 17 stores driving models and weighting coefficients in an associated manner.

With reference to FIG. 11A again, the description of the first weighting calculation processing will be continued.

After storing, in model storage 17, the calculated weighting coefficients, weighting coefficient calculator 55 determines whether any unselected classification categories is present among the one or more classification categories (step S280).

In the process of step S280, when an unselected classification category is present (step S280: Yes), the first weighting calculation processing proceeds again to the process of step S210.

In the process of step S280, when an unselected classification category is not present (step S280: No), the first weighting calculation processing ends.

FIG. 11B is a flowchart of the second weighting calculation processing performed by weighting coefficient calculator 55.

When the second weighting coefficient calculation processing starts, weighting coefficient calculator 55 selects an unselected classification category from among the one or more classification categories (step S310). Here, “unselected classification category” refers to a classification category that has not yet been selected within the loop processing formed of the process of step S310 to the process of step S380: Yes to be described later.

After an unselected classification category is selected, weighting coefficient calculator 55 separates the vehicle control signals included in the selected classification category into training data for a training machine learning model and verification data for verifying the accuracy of the data classification in the selected classification category, using the machine learning model trained using the training data (step S312).

After training the machine learning model using the training data separated in the process of step S312, driving model trainer 54 then verifies the accuracy of the data classification in the classification category, using the machine learning model trained using such training data, and the verification data (step S314).

After the accuracy of the data classification is verified, weighting coefficient calculator 55 determines whether the verified accuracy of the data classification is higher than or equal to a first threshold (step S320).

In the process of step S320, when the verified accuracy of the data classification is higher than or equal to the first threshold (step S320: Yes), weighting coefficient calculator 55 calculates the weighting coefficient as 1 (step S330).

In the process of step S320, when the verified accuracy of the data classification is not higher than or equal to the first threshold (step S320: No), weighting coefficient calculator 55 further determines whether the verified accuracy of the data classification is higher than or equal to a second threshold, which is smaller than the first threshold (step S340).

In the process of step S340, when the verified accuracy of the data classification is higher than or equal to the second threshold (step S340: Yes), weighting coefficient calculator 55 calculates the weighting coefficient as a value that is greater than 0 and smaller than 1. In so doing, weighting coefficient calculator 55 calculates the weighting coefficient to cause the value of the weighting coefficient to be larger as the verified accuracy of the data classification is higher, in accordance with the verified accuracy of the data classification (step S350).

In the process of step S340, when the verified accuracy of the data classification is not higher than or equal to the second threshold (step S340: No), weighting coefficient calculator 55 calculates the weighting coefficient as 0 (step S360).

When the process of step S330 ends, when the process of step S350 ends, and when the process of step S360 ends, weighting coefficient calculator 55 stores, in model storage 17, the calculated weighting coefficients and the corresponding driving models in an associated manner (step S370).

After storing, in model storage 17, the calculated weighting coefficients, weighting coefficient calculator 55 determines whether any unselected classification categories is present among the one or more classification categories (step S380).

In the process of step S380, when an unselected classification category is present (step S380: Yes), the second weighting calculation processing proceeds again to the process of step S310.

In the process of step S380, when an unselected classification category is not present (step S380: No), the second weighting calculation processing ends.

Note that weighting coefficient calculator 55 may calculate the weighting coefficients by performing processing other than the first weighting calculation processing or the second weighting calculation processing described above.

When the distribution of vectors in the feature space representing a change in the velocity or/and the angular velocity of each of a plurality of mobile objects in the respective driving patterns are as shown in the classification results in the feature space in FIG. 10, for example, weighting coefficient calculator 55 may calculate a weighting coefficient to cause the value of the weighting coefficient to be relatively large for a driving model of a driving pattern corresponding to a class where the difference in the distance between vectors within the same class in the feature space is relatively small (here, class (1) and class (3)), and to cause the value of the weighting coefficient to be relatively small for a driving model of a driving pattern corresponding to a class where the difference in the distance between vectors within the same class in the feature space is relatively large (here, class (2) and class (4)).

In this case, weighting coefficient calculator 55 calculates relatively large weighting coefficients (here, 0.9 and 0.9) for the driving model of the driving pattern corresponding to class (1) and for the driving model of the driving pattern corresponding to class (3), which are classes where the difference in the distance between vectors within the same class in the feature space is relatively small, and may calculate relatively small weighting coefficients (here, 0.3 and 0.1) for the driving model of the driving pattern corresponding to class (4) and for the driving model of the driving pattern corresponding to class (2), which are classes where the difference in the distance between vectors within the same class in the feature space is relatively large.

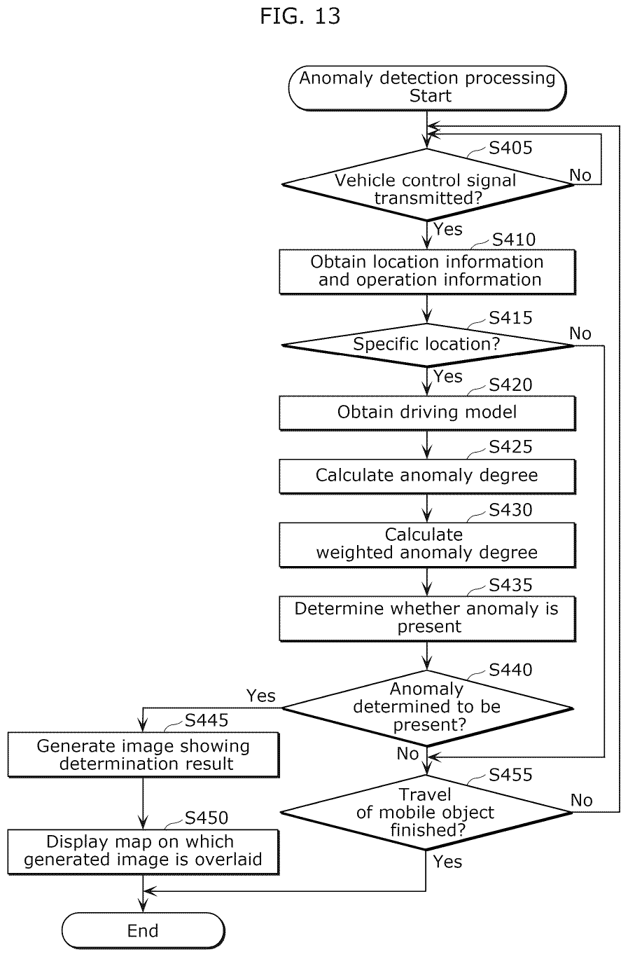

FIG. 13 is a flowchart of the anomaly detection processing performed by anomaly detection device 10.

As shown in FIG. 13, when the anomaly detection processing starts, information obtainer 11 waits until a vehicle control signal including location information and operation information is newly transmitted from mobile object 20 (repeats step S405: No). When a vehicle control signal is transmitted from mobile object 20 (step S405: Yes), information obtainer 11 receives the transmitted vehicle control signal, and obtains, from the received vehicle control signal, the location information and the operation information included in such vehicle control signal (step S410).

After the location information and the operation information are obtained, model obtainer 12 determines whether the location indicated by the obtained location information is one of the one or more predetermined specific locations (step S415).

In the process of step S415, when the location indicated by the obtained location information is one of the one or more predetermined specific locations (step S415: Yes), model obtainer 12 obtains, from model storage 17, a driving model associated with the location indicated by the obtained location information (step S420). In so doing, model obtainer 12 identifies the driving pattern of mobile object 20 at such point from a change in the location indicated by the location information of mobile object 20 at such point, and obtains the driving model of the driving pattern that matches the identified driving pattern. Stated differently, model obtainer 12 obtains, from model storage 17, the driving model of the driving pattern that matches the identified driving pattern, from among the one or more driving models associated with the location indicated by the obtained location information.

After the driving model is obtained, anomaly degree calculator 13 calculates the anomaly degree indicating the degree of an anomaly related to the travel of mobile object 20, on the basis of the operation information obtained in the process of step S410 and the driving model obtained in the process of step S420 (step S425).

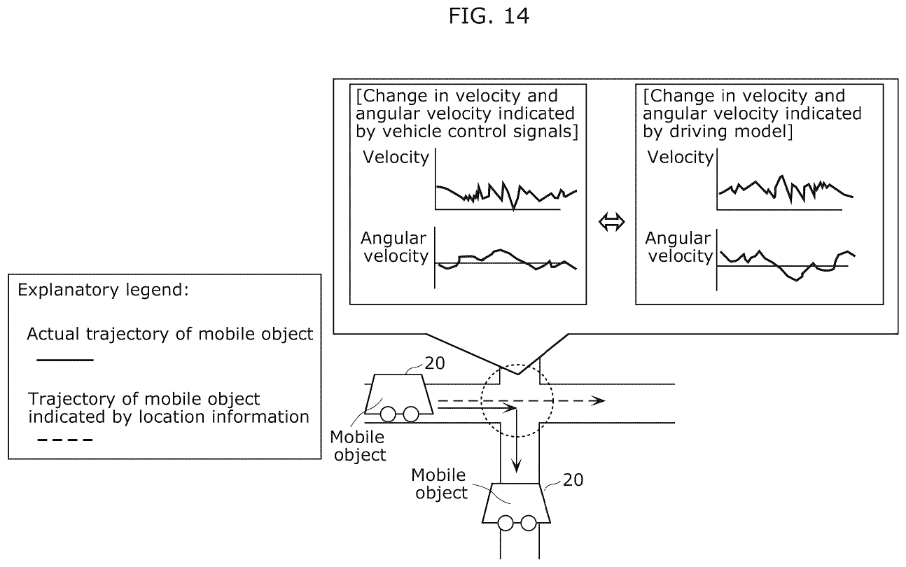

FIG. 14 is a schematic diagram showing an example of how anomaly degree calculator 13 calculates an anomaly degree related to the travel of mobile object 20, which is specifically an anomaly degree related to location information of mobile object 20.

In FIG. 14, the broken arrow represents the trajectory of the driving of mobile object 20 indicated by the items of location information transmitted from mobile object 20, while the solid arrow represents the actual trajectory of the driving of mobile object 20.

The example shown in FIG. 14 shows an example case where the items of location information transmitted from mobile object 20 have been tampered with and altered by a malicious attacker, as a result of which mobile object 20 appears as if mobile object 20 were driving straight ahead, despite that mobile object 20 is actually turning right.

As shown in FIG. 14, when the items of location information transmitted from mobile object 20 have been tampered with, a difference occurs between the locations of mobile object 20 indicated by the items of location information transmitted from mobile object 20 and the actual locations of mobile object 20.

Here, a possible method of detecting whether location information has been tampered with is a method in which whether an anomaly (tampering) is present in the location information is determined on the basis of information that is considered difficult for an attacker to tamper with, such as velocity and angular velocity.

One such possible method is a method in which an anomaly is determined to be present when the difference between the estimated location and the location indicated by location information becomes greater than or equal to a certain threshold, using a technique known as “odometry” for estimating a location from the velocity and the angular velocity. However, the use of such a simple method can result in a relatively large error in the location estimated from the velocity and the angular velocity, due to friction or other causes. Consequently, false positives/false negatives in anomaly detection can occur.

An example of the countermeasures against it is the use of a method, as shown in FIG. 14, in which a change in the velocity and the angular velocity (time-series data) in a specific driving pattern at a specific location is learned, and the difference is checked between the learned change in the velocity and the angular velocity (time-series data) and a change in the actual velocity and angular velocity (time-series data). With this, it is possible to reduce the occurrence of false positives/false negatives in anomaly detection.

In the example shown in FIG. 14, model obtainer 12 identifies, from the change in the location of mobile object 20 indicated by the items of location information, the driving pattern of mobile object 20 at such point, and then obtains the driving model corresponding to the identified driving pattern. Anomaly degree calculator 13 then compares the change in the velocity and the angular velocity (time-series data) indicated by the obtained driving model with the change in the velocity and the angular velocity (time-series data) transmitted from mobile object 20, thereby calculating the anomaly degree related to the location information of mobile object 20.

In this case, the anomaly degree may be calculated, for example, by calculating the difference between the items of time-series data, using a known method such as Dynamic Time Warping (DTW), and then determining whether the calculated difference is at a threshold.

With reference to FIG. 13 again, the description of the anomaly detection processing will be continued.

After the anomaly degree is calculated, anomaly degree adjuster 14 adjusts the calculated anomaly degree. Stated differently, anomaly degree adjuster 14 calculates the weighted anomaly degree by multiplying the calculated anomaly degree by the weighting coefficient corresponding to such anomaly degree (step S430).

In so doing, anomaly degree adjuster 14 may calculate the weighted anomaly degree, for example, by multiplying the calculated anomaly degree by the weighting coefficient associated with the location indicated by the location information obtained in the process of step S410. Anomaly degree adjuster 14 may also calculate the weighted anomaly degree, for example, by multiplying the calculated anomaly degree by the weighting coefficient associated with the driving model obtained in the process of step S420.

When the vehicle control signal transmitted from mobile object 20 includes time information indicating time and associated with the location information, for example, information obtainer 11 may further obtain, in the process of step S410, the time information associated with the location information, and anomaly degree adjuster 14 may calculate a weighted anomaly degree, in the process of step S430, by multiplying the calculated anomaly degree by the weighting coefficient that is based on the time indicated by the time information obtained in the process of step S410.

After the weighted anomaly degree is calculated, determiner 15 determines whether an anomaly related to the travel of mobile object 20 is present, on the basis of the calculated weighted anomaly degree (step S435). Here, when one or more weighted anomaly degrees are calculated in the loop processing formed of the process of step S405: Yes to the process of step S455: No to be described later, determiner 15 determines whether an anomaly related to the travel of mobile object 20 is present on the basis of the one or more weighted anomaly degrees.

Determiner 15 may calculate, for example, the sum of the one or more weighted anomaly degrees and determine that an anomaly related to the travel of mobile object 20 is present when the calculated sum is greater than or equal to a threshold.

Also, to further reduce the influence of older weighted anomaly degrees and further increase the influence of more recent weighted anomaly degrees among the one or more weighted anomaly degrees, for example, determiner 15 may use decay coefficient β(t) to calculate cumulative anomaly degree Z that is based on the one or more weighted anomaly degrees, and may determine that an anomaly related to the travel of mobile object 20 is present when cumulative anomaly degree Z calculated is higher than or equal to the threshold.

Here, decay coefficient β(t) is a coefficient that is set to cause the value of the coefficient to be smaller as the difference from the current time is larger.

In this case, when the weighted anomaly degree at time t is taken as z(t), cumulative anomaly degree Z may be calculated, for example, by Z=β(t1)×z(t1)+β(t2)×z(t2)+β(t3)×z(t3)+ . . .

When determiner 15 determines, in the process of step S435, that an anomaly related to the travel of mobile object 20 is present (step S440: Yes), outputter 16 generates an image showing the result of the determination (step S445). Outputter 16 then displays, onto display device 40, a map on which the generated image is superimposed (step S450).

In so doing, to notify the user of anomaly detection device 10 (e.g., person who is monitoring mobile object 20) of the result of the determination in a manner the enables the user to easily understand the characteristics of the anomaly, for example, outputter 16 may generate an image showing various items of information in a visualized form.

Examples of the various items of information may include: information for displaying a change in the location of mobile object 20 estimated from the velocity and the angular velocity of mobile object 20 and a change in the location of mobile object 20 indicated by the location information transmitted from mobile object 20 on the corresponding map in an superimposed manner; information for displaying a change in the velocity and the angular velocity of mobile object 20 during the travel of mobile object 20 and a change in the velocity and the angular velocity during the past travel of mobile object 20 that are aligned with each other; and when a vehicle control signal transmitted from mobile object 20 includes camera video captured by mobile object 20, for example, information for displaying video that results from cutting out the corresponding portion from the camera video.

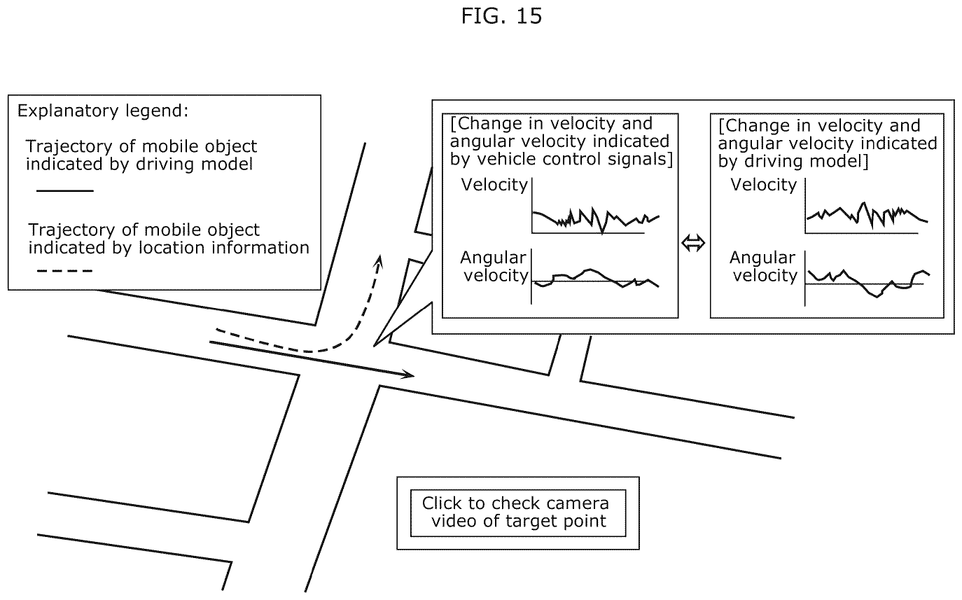

FIG. 15 is a schematic diagram showing an example of the image displayed onto display device 40 by outputter 16.

As shown in FIG. 15, the image displayed on display device 40 by outputter 16 includes: the trajectory of the driving of mobile object 20 indicated by the items of location information transmitted from mobile object 20, as represented by the broken arrow; and the trajectory of the driving of mobile object 20 indicated by the driving model in the driving pattern that matches the driving pattern identified from the velocity and the angular velocity transmitted from mobile object 20, as represented by the solid arrow.

The image displayed onto display device 40 by outputter 16 also shows the change in the velocity and the angular velocity during the travel of mobile object 20 that are aligned with the change in the velocity and the angular velocity during the past travel of mobile object 20, that is, the change in the velocity and the angular velocity during the travel of mobile object 20 indicated by the driving model.

The image displayed onto display device 40 by outputter 16 also shows a button including a link to the camera video captured by mobile object 20 at the corresponding location.

By displaying such an image onto display device 40, it is possible, for example, to help the person who is monitoring the travel of mobile object 20 recognize the characteristics of the anomaly in the driving of mobile object 20 and prompt such person to initiate the analysis on the travel of mobile object 20.

With reference to FIG. 13 again, the description of the anomaly detection processing will be continued.

In the process of step S415, when the location indicated by the obtained location information is not one of the one or more predetermined specific locations (step S415: No), and when determiner 15 determines, in the process of step S435, that an anomaly related to the travel of mobile object 20 is not present (step S440: No), information obtainer 11 determines whether the travel of mobile object 20 has finished (step S455).

In the process of step S455, when information obtainer 11 determines that the travel of mobile object 20 has not finished (step S455: No), the anomaly detection processing proceeds again to the process of step S405.

When the process of step S450 ends, and when information obtainer 11 determines, in the process of step S455, that the travel of mobile object 20 has finished (step S455: Yes), the anomaly detection processing ends.

### Considerations

According to anomaly detection device 10 having the above configuration, it is possible to calculate the anomaly degree of mobile object 20 at a specific location on the basis of the operation information indicating an operation of mobile object 20 and associated with the location information indicating such specific location at which mobile object 20 operates in a driving pattern that is suitable in terms of verifying the validity of the location information and the driving model associated with such specific location, and to determine whether an anomaly related to the travel of mobile object 20 is present on the basis of the calculated anomaly degree. This enables anomaly detection device 10 described above to determine that an anomaly related to the travel of mobile object 20 is present, when the obtained location information has been tampered with.

As described above, according to anomaly detection device 10 described above, it is possible to detect an anomaly related to the travel of mobile object 20 even when location information of such mobile object 20 has been tampered with by a malicious attacker.

### Added Notes

Examples of the technique disclosed in the present application have been described on the basis of the embodiment, but the present disclosure is not limited to such embodiment. The scope of one or more aspects of the present disclosure may also include an embodiment achieved by making various modifications to the embodiment that can be conceived by those skilled in the art and an embodiment achieved by combining some of the elements in different embodiments or variations, without departing from the essence of the present disclosure.

(1) Algorithms for self-driving of the one or more mobile objects, including mobile object 20, can differ from manufacturer to manufacturer. For this reason, driving patterns of the one or more mobile objects can also differ among different manufacturers.

In view of this, classifier 53 may classify vehicle control signals into classification categories that differ from manufacturer to manufacturer, driving model trainer 54 may generate driving models that differ from manufacturer to manufacturer, and model storage 17 may store driving models that differ from manufacturer to manufacturer.

In this case, model storage 17 stores the driving models and the corresponding manufacturers in an associated manner, and model obtainer 12 obtains, from model storage 17, the driving model associated with the manufacturer of mobile object 20.

Also in this case, weighting coefficient calculator 55 may calculate the weighting coefficient for each driving pattern independently on a manufacturer basis.

Note that, the number of vehicle control signals per classification category may become relatively small as a result of classifier 53 classifying the vehicle control signals into classification categories that differ on a manufacturer basis. In such a case, classifier 53 may merge vehicle control signals corresponding to a plurality of points whose driving patterns are similar to each other and classify the merged vehicle control signals into the same classification category. Stated differently, for example, classifier 53 may classify the vehicle control signals for driving pattern P01 and driving pattern P02 in area in area A01 and area A02 into the same classification category. In this case, classifier 53 may classify the vehicle control signals using a method such as hierarchical clustering analysis in machine learning.

(2) These general and specific aspects of the present disclosure may be implemented using a system, a device, a method, an integrated circuit, a program, or a non-transitory recording medium such as a computer-readable CD-ROM, or any combination of systems, devices, methods, integrated circuits, programs, or non-transitory recording media. The present disclosure may also be realized, for example, in the form of a program for causing a computer device to execute the processes performed by anomaly detection device 10.

### INDUSTRIAL APPLICABILITY

The present disclosure is widely applicable for use as, for example, anomaly detection devices that detect anomalies in vehicles.

1. An anomaly detection method comprising:
obtaining first location information indicating a location of a mobile object and first operation information indicating an operation of the mobile object and associated with the first location information;
when the location indicated by the first location information is a first specific location, obtaining a first driving model that is generated based on first travel data related to past travel of at least one mobile object and associated with the first specific location, the at least one mobile object being included in one or more mobile objects including the mobile object;
when the location indicated by the first location information is the first specific location, calculating a first anomaly degree indicating a degree of an anomaly related to travel of the mobile object, based on the first operation information and the first driving model;
determining whether an anomaly related to the travel of the mobile object is present, based on the first anomaly degree; and
outputting a result of the determining to outside.

2. The anomaly detection method according to claim 1,
wherein the obtaining of the first location information and the first operation information further includes obtaining: second location information indicating a location of the mobile object; and second operation information indicating an operation of the mobile object and associated with the second location information,
when the location indicated by the second location information is a second specific location, the obtaining of the first driving model further includes obtaining a second driving model that is generated based on second travel data related to the past travel of the at least one mobile object and associated with the second specific location;
when the location indicated by the second location information is the second specific location, the calculating of the first anomaly degree further includes calculating a second anomaly degree indicating a degree of an anomaly related to the travel of the mobile object, based on the second operation information and the second driving model, and
the determining is performed based on the first anomaly degree and the second anomaly degree.

3. The anomaly detection method according to claim 2, further comprising:
calculating a first weighted anomaly degree based on the first anomaly degree and a first weighting coefficient that is associated with the location indicated by the first location information, and calculating a second weighted anomaly degree based on the second anomaly degree and a second weighting coefficient that is associated with the location indicated by the second location information,
wherein the determining is performed based on the first weighted anomaly degree and the second weighted anomaly degree.

4. The anomaly detection method according to claim 2, further comprising:
calculating a third weighted anomaly degree based on the first anomaly degree and a third weighting coefficient that is associated with the first driving model, and calculating a fourth weighted anomaly degree based on the second anomaly degree and a fourth weighting coefficient that is associated with the second driving model,
wherein the determining is performed based on the third weighted anomaly degree and the fourth weighted anomaly degree.

5. The anomaly detection method according to claim 2,
wherein the obtaining of the first location information and the first operation information further includes obtaining: first time information indicating a first time and associated with the first location information; and second time information indicating a second time and associated with the second location information,
the anomaly detection method further comprises:
calculating a fifth weighted anomaly degree based on the first anomaly degree and a fifth weighting coefficient that is based on the first time indicated by the first time information, and calculating a sixth weighted anomaly degree based on the second anomaly degree and a sixth weighting coefficient that is based on the second time indicated by the second time information, and
the determining is performed based on the fifth weighted anomaly degree and the sixth weighted anomaly degree.

6. The anomaly detection method according to claim 1,
wherein the obtaining of the first driving model includes obtaining a third driving model that is the first driving model associated with a manufacturer of the mobile object,
the calculating of the first anomaly degree includes calculating a third anomaly degree that is the first anomaly degree that is based on the first operation information and the third driving model, and
the determining is performed based on the third anomaly degree.

7. The anomaly detection method according to claim 1,
wherein the first operation information includes at least one of velocity information indicating a velocity of the mobile object or angular velocity information indicating an angular velocity of the mobile object.

8. The anomaly detection method according to claim 1,
wherein the outputting is performed by generating an output image and displaying the output image onto a display, the output image being an image showing the result of the determining that is superimposed on a map including the location indicated by the first location information.

9. The anomaly detection method according to claim 1, further comprising:
generating the first driving model based on the first travel data.

10. The anomaly detection method according to claim 9,
wherein the generating includes:
generating one or more driving models including the first driving model, based on a plurality of items of travel data including the first travel data; and
individually classifying the plurality of items of travel data into one of a plurality of classification categories that include one or more classification categories and correspond one-to-one to the one or more driving models, and generating the one or more driving models based on one or more of the plurality of items of travel data classified into the one or more classification categories.

11. The anomaly detection method according to claim 10, further comprising:
calculating, for each of the one or more driving models, a weighting coefficient indicating a reliability of the driving model and associated with the driving model.

12. An anomaly detection device comprising:
an information obtainer that obtains first location information indicating a location of a mobile object and first operation information indicating an operation of the mobile object and associated with the first location information;
a model obtainer that obtains a first driving model that is generated based on first travel data related to past travel of at least one mobile object and associated with a first specific location, when the location indicated by the first location information is the first specific location, the at least one mobile object being included in one or more mobile objects including the mobile object;
an anomaly degree calculator that calculates a first anomaly degree indicating a degree of an anomaly related to travel of the mobile object, based on the first operation information and the first driving model, when the location indicated by the first location information is the first specific location;
a determiner that determines whether an anomaly related to the travel of the mobile object is present, based on the first anomaly degree; and
an outputter that outputs a determination result to outside.

13. A non-transitory computer-readable recording medium having recorded thereon a program for causing a computer to execute anomaly detection processing,
wherein the anomaly detection processing includes:
obtaining first location information indicating a location of a mobile object and first operation information indicating an operation of the mobile object and associated with the first location information;
when the location indicated by the first location information is a first specific location,
obtaining a first driving model that is generated based on first travel data related to past travel of at least one mobile object and associated with the first specific location, the at least one mobile object being included in one or more mobile objects including the mobile object;
when the location indicated by the first location information is the first specific location,
calculating a first anomaly degree indicating a degree of an anomaly related to travel of the mobile object, based on the first operation information and the first driving model;
determining whether an anomaly related to the travel of the mobile object is present, based on the first anomaly degree; and
outputting a result of the determining to outside.
